(19) United States
(12) Patent Application Publication
(10) Pub. No.: US 2024/0227075 A9
(43) Pub. Date: Jul. 11, 2024

(54) SUBSTRATE TREATING APPARATUS AND METHOD FOR SUBSTRATE TREATING

(71) Applicant: SEMES CO., LTD., Cheonan-si (KR)

(72) Inventors: Tae Shin KIM, Suwon-si (KR); Ki Hoon CHOI, Cheonan-si (KR); Tae Hee KIM, Yongin-si (KR); Sang Gun LEE, Seoul (KR); Jin Yeong SUNG, Hwaseong-si (KR); Jang Jin LEE, Seoul (KR)

(73) Assignee: SEMES CO., LTD., Cheonan-si (KR)

(21) Appl. No.: 18/480,393

(22) Filed: Oct. 3, 2023

(30) Foreign Application Priority Data
Oct. 21, 2022 (KR) 10-2022-0136336

(51) Int. Cl. B23K 26/12; B23K 26/08; B23K 26/362; H01L 21/768

(52) U.S. Cl. CPC B23K 26/128; B23K 26/0884; B23K 26/362; H01L 21/76894; B23K 2101/40

(57) ABSTRACT

Embodiments of the inventive concept provide a substrate treating apparatus and a substrate treating method for not letting an irradiation region of a laser deviate from a target region, even if a shaking angle of a chemical deviates from an allowable range due to a vibration or an airflow. The inventive concept provides a substrate treating apparatus. The substrate treating apparatus includes: a substrate support unit configured to support a substrate having a chemical coated thereon; a laser generation unit configured to irradiate a laser to the substrate; and a light-transmitter positioned along a path at which the laser is irradiated.

### CROSS-REFERENCE TO RELATED APPLICATIONS

A claim for priority under 35 U.S.C. § 119 is made to Korean Patent Application No. 10-2022-0136336 filed on Oct. 21, 2022, in the Korean Intellectual Property Office, the entire contents of which are hereby incorporated by reference.

### BACKGROUND

Embodiments of the inventive concept described herein relate to a substrate treating apparatus and a substrate treating method, more specifically, a substrate treating apparatus and a substrate treating method for treating a substrate using a laser.

Among manufacturing processes of a semiconductor substrate, there is an exposing process. The exposing process is a very important process of forming a pattern on the substrate by exposing a photoresist coated on the substrate to cure only a specific pattern of the photoresist irradiated with a light, and to remove an uncured region through a developing process.

In such an exposing process, a mask printed with a thin film layer is positioned in a region other than a light transmission pattern so a light does not pass through, and a light is irradiated to pass through the light transmission pattern of the mask, and a light which has passed through the light transmission pattern cures the photoresist of a wafer into a specific pattern.

In this case, the pattern formed on the mask forms the thin film layer at which a light does not pass through to a base substrate of a dielectric material, and after the photoresist is coated, the photoresist is cured in a pattern form using a laser or an electron beam, the photoresist is selectively etched to form a pattern form.

After that, a mask defect inspection process is performed to check whether the mask is formed differently from a required specification such as a critical dimension of the pattern, and if the critical dimension of the pattern is formed differently from the specification, a correction process of etching the pattern is performed. Usually, the pattern is corrected by etching the thin film layer using the laser.

At this time, regarding a process of removing the thin film layer using a conventional laser, FIG. 1 is a process of removing the thin film layer using the conventional laser. As shown in FIG. 1, a conventional process uses a correcting method of coating the chemical 2 at a top space of the mask, and irradiating the laser to the top portion of the chemical 2 to etch a target region 1a of the thin film layer.

In this case, the laser passes through the chemical 2 and is irradiated to the thin film layer, and the laser is irradiated to the target region 1a with a certain incident angle θᵢ to the chemical 2 having a certain height t1. At this time, the chemical 2 generates a shaking angle α by a shaking of a surface due to an influence such as a vibration or an air flow, and the laser is incident by being refracted as much as a refraction angle θᵣ due to an influence of the shaking angle α.

Then, a deviation δᵣ is generated from the target region 1a in a final irradiation position of the laser due to the incident angle θᵢ and the refraction angle θᵣ, which is expressed in the following formula 1.

δᵣ=t₁(tan θᵢ−tan θᵣ) Equation 1

Accordingly, further referring to FIG. 2 to FIG. 5 to look at various cases in which the deviation δᵣ from the target region 1a occurs, FIG. 2 to FIG. 4 are plan views illustrating a radius of a target and a radius of a laser depending on a position of the laser, and FIG. 5 is a graph illustrating an allowable range of the incident angle θᵢ of the laser and the shaking angle α of the chemical 2.

First, FIG. 2 shows a state in which the incident angle θᵢ of the laser and the refraction angle θᵣ of the chemical 2 remain unchanged, and a state in which a center of the target region and a center of the laser are matched to ideally irradiate the laser.

Next, FIG. 3 shows a state in which the incident angle θᵢ of the laser and the refraction angle θᵣ of the chemical 2 occur to some extent but are positioned within the allowable range shown in FIG. 5. In this case, there is a certain deviation between the center of the target region 1a and the center of the laser, but the target region 1a is positioned within the radius of the laser and therefore may be corrected.

FIG. 4 shows a state in which the incident angle θᵢ of the laser and the refraction angle θᵣ of the chemical 2 are outside the allowable range, and a state in which the laser cannot etch the target region 1a because the radius of the laser cannot cover an entirety of the target region 1a.

As shown in FIG. 4, a problem of not being able to normally correct a mask pattern occurs mainly because the shaking angle α of the chemical 2 deviates from the allowable range due to a vibration or an airflow, and a technical solution is needed to solve this problem.

### SUMMARY

Embodiments of the inventive concept provide a substrate treating apparatus and a substrate treating method for not letting an irradiation region of a laser deviate from a target region, even if a shaking angle of a chemical deviates from an allowable range due to a vibration or an airflow.

The inventive concept provides a substrate treating apparatus. The substrate treating apparatus includes a substrate support unit configured to support a substrate having a chemical coated thereon; a laser generation unit configured to irradiate a laser to the substrate; and a light-transmitter positioned along a path at which the laser is irradiated.

In an embodiment, the substrate treating apparatus further includes a light-transmitter transfer unit coupled to the light-transmitter and configured to transfer the light-transmitter.

In an embodiment, a cross section of the light-transmitter is shaped as any one among a circle, an oval, a square, or a polygon.

In an embodiment, the light-transmitter is positioned so a bottom portion thereof is immersed in the chemical.

In an embodiment, the bottom portion of the light-transmitter is positioned apart from the substrate.

In an embodiment, the light-transmitter is formed having an outer surface inclined toward a bottom direction so a diameter of a cross section becomes smaller toward a bottom.

In an embodiment, the substrate treating apparatus further includes an outer coupling body formed to surround an outer side of the light-transmitter.

In an embodiment, the outer coupling body is formed at a region aside from a top and a bottom of the light-transmitter, and the outer coupling body is formed having a lower refractive index than a refractive index of the light-transmitter or having a reflective surface with a high reflectivity on an inner side surface.

In an embodiment, the light-transmitter is positioned only at a partial region among a laser irradiation path.

In an embodiment, the substrate treating apparatus of further includes a diffusion unit configured to diffuse a laser which has passed through the light-transmitter, and which is composed at a bottom of the light-transmitter.

In an embodiment, the diffusion unit has a plurality of grooves or a plurality of protrusions which are irregularly distributed.

The inventive concept provides a substrate treating method. The substrate treating method includes seating a substate on a substrate support unit; positioning a laser generation unit at a top space of the substrate by transferring with a laser transfer unit; positioning a light-transmitter along a laser path of which a laser is irradiated from the laser generation unit with a light-transmitter transfer unit; irradiating the laser from the laser generation unit to the light-transmitter and transmitting the laser to a target region of the substrate by the light-transmitter; and etching the substrate by a laser which has reached the target region.

In an embodiment, a bottom portion of the light-transmitter is positioned to be immersed in a chemical at the positioning the light-transmitter.

In an embodiment, a bottom portion of the light-transmitter is positioned apart from the substrate.

In an embodiment, the light-transmitter is formed having an outer surface inclined toward a bottom direction so a diameter of a cross section becomes smaller toward a bottom.

In an embodiment, the substrate treating method further includes an outer coupling body formed to surround an outer side of the light-transmitter.

In an embodiment, the outer coupling body is formed at a region aside from a top and a bottom of the light-transmitter, and the outer coupling body is formed having a lower refractive index than a refractive index of the light-transmitter or having a reflective surface with a high reflectivity on an inner side surface.

In an embodiment, the light-transmitter is positioned only at a partial region among a laser irradiation path.

In an embodiment, the substrate treating method further includes a diffusion unit at a bottom of the light-transmitter configured to diffuse a laser which has passed through the light-transmitter.

The inventive concept provides a substrate treating apparatus. The substrate treating apparatus includes a substrate support unit configured to support a substrate having a chemical coated thereon; a laser generation unit configured to irradiate a laser to the substrate; a light-transmitter positioned along a path at which the laser is irradiated; a light-transmitter transfer unit coupled to the light-transmitter and configured to transfer the light-transmitter; an outer coupling body formed to surround an outer side of the light-transmitter; and a diffusion unit configured to diffuse a laser which has passed through the light-transmitter, and which is composed at a bottom of the light-transmitter, and wherein a cross section of the light-transmitter is shaped as any one among a circle, an oval, a square, or a polygon, the light-transmitter is positioned to a bottom portion thereof is immersed in the chemical, the bottom portion of the light-transmitter is positioned apart from the substrate, the light-transmitter is formed having an outer surface inclined toward a bottom direction so a diameter of a cross section becomes smaller toward a bottom, the outer coupling body is formed at a region aside from a top and a bottom of the light-transmitter, the outer coupling body is formed having a lower refractive index than a refractive index of the light-transmitter or having a reflective surface with a high reflectivity on an inner side surface, the light-transmitter is positioned only at a partial region among a laser irradiation path, and the diffusion unit has a plurality of grooves or a plurality of protrusions which are irregularly distributed.

According to an embodiment of the inventive concept, an irradiation region of a laser is prevented from deviating from a target region, even if a shaking angle of a chemical deviates from an allowable range due to a vibration or an airflow.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a conventional process of coating a chemical on a top portion of a mask and etching a thin film layer by irradiating a laser from above of the chemical.

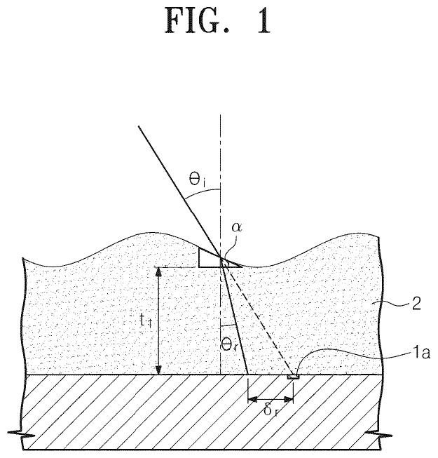

FIG. 2 to FIG. 4 are plan views illustrating a radius of a target and a radius of the laser according to a position of the laser.

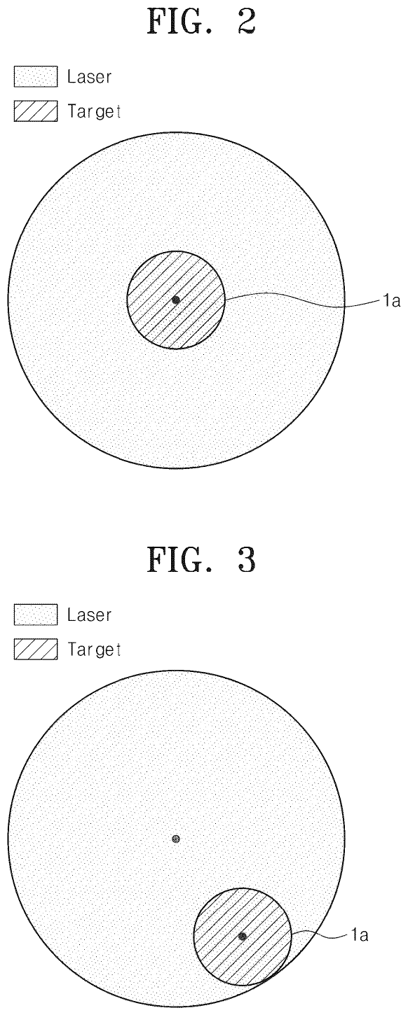

FIG. 5 is a graph illustrating an acceptable range of an incident angle of the laser and a shaking angle of the chemical.

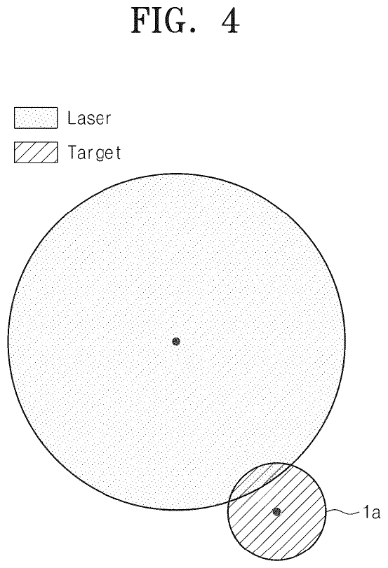

FIG. 6 is a block view of a substrate treating apparatus according to an embodiment of the inventive concept.

FIG. 7 is an enlarged block view of a first light transmitter illustrated in FIG. 6.

FIG. 8 is a perspective view of a substrate treating method according to an embodiment of the inventive concept.

FIG. 9 is a block view of the substrate treating apparatus according to another embodiment of the inventive concept.

FIG. 10 is a block view of the substrate treating apparatus according to another embodiment of the inventive concept.

FIG. 11 is a block view of the substrate treating apparatus according to another embodiment of the inventive concept.

FIG. 12 is a block view of the substrate treating apparatus according to another embodiment of the inventive concept.

FIG. 13 is a block view of the substrate treating apparatus according to another embodiment of the inventive concept.

FIG. 14 is an image of an energy density distribution of the laser before a diffusion unit shown in FIG. 13 is formed.

FIG. 15 is an image of an energy density of a laser which has passed through the diffusion unit after the diffusion unit shown in FIG. 13 is formed.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

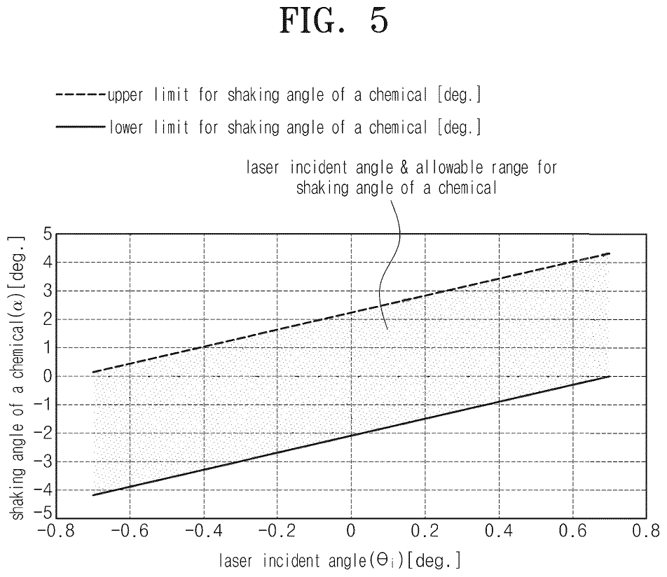

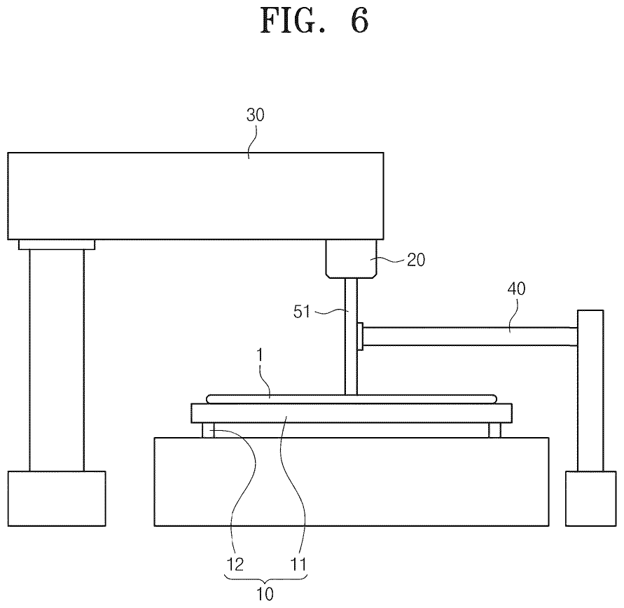

FIG. 6 is a block view of a substrate treating apparatus according to an embodiment of the inventive concept. FIG. 7 is an enlarged block view of a first light transmitter illustrated in FIG. 6.

As shown in FIG. 6 and FIG. 7, the substrate treating apparatus according to an embodiment of the inventive concept includes a substrate support unit 10, a laser generation unit 20, a laser transfer unit 30, a light transmitter transfer unit 40, and a first light transmitter 51.

Prior to explaining a detailed configuration of the embodiment, in the case of the embodiment, a chemical 2 is coated with a thickness of 2 mm on a substrate 1, a refractive index of the chemical 2 is 1.333, a wavelength of a laser is 532 nm, a diameter of the laser is 100 μm, and a diameter of the first light transmitter 51 is 120 μm.

The substrate support unit 10 is a configuration which supports the substrate 1 and includes a substrate support 11 and a vibration absorber 12 placed under the substrate support 11 to absorb a vibration transmitted to the substrate support 11. In this embodiment, the substrate 1 consists of a mask used in an exposing process, and in this case, the mask consists of a mask printed with a patterned thin film layer on a top surface, and is exemplified by etching a critical dimension of the thin film layer by a laser generated by the laser generation unit 20. However, in the inventive concept, the substrate 1 is not limited to a mask, and the substrate 1 may consist of all substrates 1 which perform an etching using the laser. In addition, in the case of the embodiment, the chemical 2 used for etching the thin film layer is coated to the top surface of the substrate 1. In addition, the critical dimension of the thin film layer is corrected by the laser on the substrate 1, and in this embodiment, a specific region of the thin film layer to which the laser is irradiated to correct the critical dimension of the substrate 1 is referred to as a target region 1a. In addition, the substrate support unit 10 can transfer the substrate 1 by changing its position to a specific position on a three-dimensional space in conjunction with a transfer robot (not shown).

The laser generation unit 20 is a configuration which generates the laser, and has a laser diode (not shown) which generates the laser, a lens which collects the laser diode, and a coupling body which provides a coupling region to combine the laser diode and the lens at a specific position. However, in the inventive concept, a detailed configuration of the laser generation unit 20 is not limited to the above configurations, and the laser generation unit 20 can be modified into any form which can etch the thin film layer by generating the laser.

The laser transfer unit 30 includes a laser generation unit 20 coupled with the laser generation unit 20 to transfer the laser generation unit 20, and a laser transfer control unit (not shown) which transmits a transfer command to the laser transfer unit to control a position of the laser transfer unit according to a preset program. Here, the laser transfer unit may be composed of a linear actuator, a multi-guided robot, and a combination thereof. Such a laser transfer unit 30 can change a position at which the laser is irradiated by transferring a position of the laser generation unit 20 according to a preset program. In addition, the laser transfer unit 30 may rotate the laser generation unit 20 in a three-dimensional space to change an angle at which the laser is irradiated. However, in the inventive concept, the laser transfer unit 30 is not limited to the above example, and it is of course possible to be transformed into any configuration which can variously change an irradiation direction and an irradiation angle of the laser by transferring or rotating the laser generation unit 20.

The light transmitter transfer unit 40 includes a light transmitter transfer part which transfers the first light transmitter 51 and a light transmitter transfer control part (not shown) which controls the light transmitter transfer unit. In this case, the light transmitter transfer part is coupled with the first light transmitter 51, and the first light transmitter 51 is transferred to a predetermined position according to a preset program's driving command set to the light transmitter transfer control part. Here, the light transmitter transfer part may be composed of a multi-lead actuator or a multi-lead robot to transfer the first light transmitter 51 in a three-dimensional space. In addition, the light transmitter transfer unit 40 may rotate the first light transmitter 51 in a three-dimensional space. The light transmitter transfer unit 40 serves to change an irradiation path of the laser by changing a position and an angle of the first light transmitter 51 in three-dimensional space. Meanwhile, the light transmitter transfer unit 40 may be selectively configured as necessary. For example, the light transmitter transfer unit 40 can be omitted if the first light transmitter 51 is integrally coupled with the laser generation unit 20 and driven integrally with the laser generation unit 20. However, in the inventive concept, the light transmitter transfer unit 40 is not limited to the above example, and the light transmitter transfer unit 40 can be modified into various configurations which can transfer or rotate the first light transmitter 51.

The first light transmitter 51 is formed in a rod shape and is placed on an irradiation path of the laser irradiated by the laser generation unit 20 to transmit the laser irradiated on the substrate 1, but the transmitted laser is not refracted outward to deviate and becomes an optical waveguide to be only reflected within an inner region to be totally reflected. Therefore, the laser transmitted through the first light transmitter 51 is irradiated as vertically as possible to the target region 1a of the substrate 1 even if a position deviation or a shaking deviation of the laser generation unit 20 occurs. For this reason, a position deviation of the laser reaching the target region 1a of the substrate 1 becomes smaller than before, so the substrate 1 is etched more precisely than before. Here, a cross-section of the first light transmitter 51 may be modified into various shapes such as a circle, an oval, a square, or a polygon depending on an etching rate or an etching type. In addition, the first light transmitter 51 may be formed of a transparent resin material such as an acrylic, or a transparent ceramic material such as a quartz. However, in the inventive concept, a material of the first light transmitter 51 is not limited to resin or ceramic materials, and of course, it can be modified into all transparent materials and implemented.

In addition, the first light transmitter 51 may be configured such that the bottom end thereof is immersed in the chemical 2. Accordingly, the laser which has passed through the first light transmitter 51 is irradiated as vertically as possible to the target region 1a of the substrate 1 by minimizing an influence of a shaking angle even if the shaking angle of the chemical 2 is caused by a vibration or an airflow. For this reason, a positional deviation of the laser reaching the target region 1a of the substrate 1 is smaller than that of the prior art, so the substrate 1 is etched more precisely than the prior art.

If a simulation is conducted using the first light transmitter 51, it can be viewed as shown in [Table 1] below. [Table 1] is a table in which the simulation has been conducted if the shaking angle occurs in the chemical 2, on of a center of the laser passing through the first light transmitter 51 and a center of the target region 1a. the incident angle θᵢ of the laser and the refraction angle θᵣ of the chemical 2

TABLE 1

| | Distance between | | Lower limit of | Higher limit of |
|---|---|---|---|---|
| Diameter of first | first light transmitter | Maximum incident | chemical shaking | chemical shaking |
| light transmitter[μm] | and target [mm] | angle of laser [deg.] | angle (deg.) | angle (deg.) |
| 120 | 1.5 | 2 | −84 | 84 |
| | 1 | 3 | | |
| | 0.5 | 7 | | |

As shown in Table 1, if the shaking angle occurs in the chemical 2, the center of the laser and the center of the target region 1a are only affected by a maximum incident angle of the laser, and not by the shaking angle of the chemical 2.

Hereinafter, a substrate treating method of the substrate treating apparatus according to an embodiment of the inventive concept will be described.

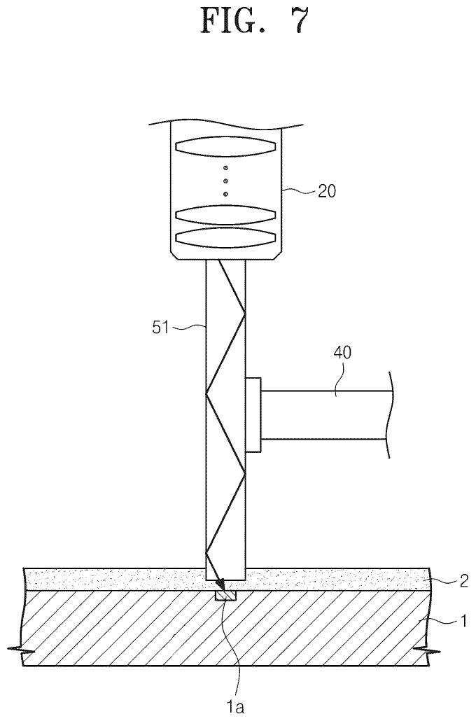

FIG. 8 is a perspective view of a substrate treating method according to an embodiment of the inventive concept.

Referring further to FIG. 8, the substrate treating method according to an embodiment of the inventive concept includes a substrate seating step S10, a laser position adjusting step S20, a light transmitter position adjusting step S30, a laser generating step S40, and a substrate etching step S50.

In the substrate seating step S10, the substrate 1 is seated on the substrate support unit 10. In this case, as described above, the substrate 1 consists of a mask printed in a specific pattern form of a thin film layer, and a target region 1a to be corrected by the laser is formed.

In the laser position adjusting step S20, the laser transfer unit 30 transfers the laser generation unit 20 and is positioned at a top portion of the substrate 1 at which the pattern modification process will proceed. In this case, the laser transfer unit 30 may adjust not only the position of the laser generation unit 20 but also the angle, if necessary.

In the light transmitter position adjusting step S30, the light transmitter transfer unit 40 adjusts the position of the first light transmitter 51 so that the first light transmitter 51 is placed on a path of the laser irradiated by the laser generation unit 20. In this case, as described above, the first light transmitter 51 is disposed in a state in which the bottom part is immersed in the chemical 2 while being spaced apart from the target region 1a.

In the laser generating step S40, the laser is irradiated from the laser generation unit 20 to the first light transmitter 51, and the laser transmitted through the first light transmitter 51 is transmitted until the target region 1a.

In the substrate etching step S50, the laser which reaches the target region 1a etches 20 the thin film layer of the substrate 1 to etch the critical dimension or shape of the pattern formed on the substrate 1.

In this way, in the substrate treating method according to an embodiment of the inventive concept, the laser irradiation region does not deviate from the target region 1a even if the shaking angle of the chemical 2 deviates from an allowable range due to a vibration or an airflow, because the first light transmitter 51 which transmits the laser transmits the laser in a state immersed in the chemical 2.

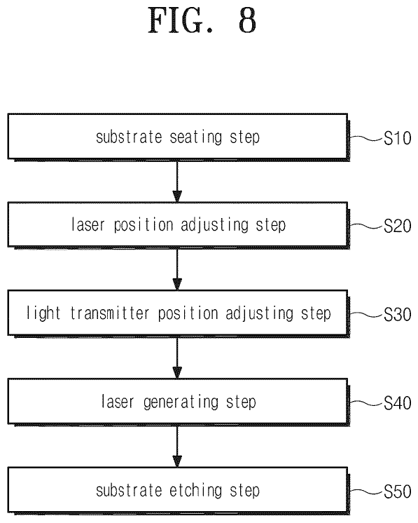

FIG. 9 is a block view of the substrate treating apparatus according to another embodiment of the inventive concept.

Referring further to FIG. 9, the substrate treating apparatus according to another embodiment of the inventive concept includes the substrate support unit 10, the laser generation unit 20, the laser transfer unit 30, the light transmitter transfer unit 40, and further includes a second light transmitter 52.

In this embodiment, the substrate support unit 10, the laser generation unit 20, the laser transfer unit 30, and the light transmitter transfer unit 40 are the same as the aforementioned embodiment, so overlapping descriptions are omitted, and the second light transmitter 52 which differs from the aforementioned embodiment will be mainly described.

The second light transmitter 52 is coupled to the light transmitter transfer unit 40 similarly as described above, to control its position. The second light transmitter 52 is placed on the irradiation path of the laser irradiated by the laser generation unit 20 in the same way as the first light transmitter 51 described above to transmit the laser irradiated to the substrate 1, but so the transmitted laser does not refract and deviate to an outer side and so it is only totally reflected within an inner region. Unlike the first light transmitter 51, the second light transmitter 52 is formed in a rod shape, and an outer surface is formed to be downwardly inclined so that a diameter of a cross-section becomes narrower toward a downward direction. Since the cross-section of the second light transmitter 52 narrows toward the bottom portion, a laser angle deviation near the bottom portion becomes less than an angle deviation of the first light transmitter 51. Therefore, since the second light transmitter 52 transmits the laser while immersed in the chemical 2, an irradiation region of the laser does not deviate from the target region 1a even if the shaking angle of the chemical 2 deviates from the allowable range due to a vibration or an airflow, and an laser angle deviation is smaller than that of the first light transmitter 51 so may more precisely etch the substrate 1 than the first light transmitter 51.

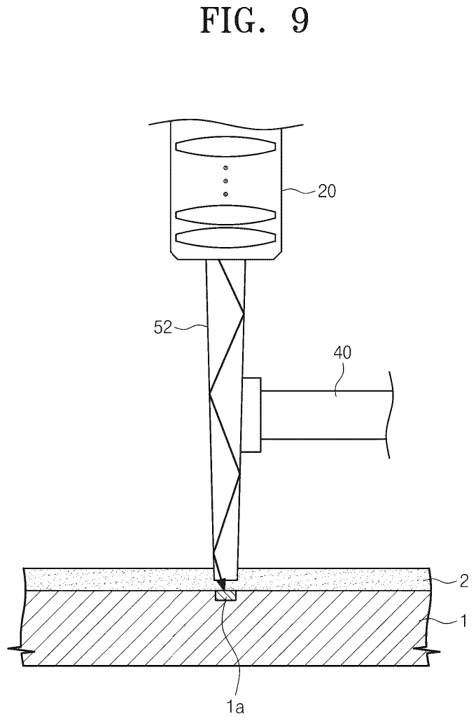

FIG. 10 is a block view of the substrate treating apparatus according to another embodiment of the inventive concept.

Referring to FIG. 10, the substrate treating apparatus according to another embodiment of the inventive concept further includes the substrate support unit 10, the laser generation unit 20, the laser transfer unit 30, the light transmitter transfer unit 40, the first light transmitter 51, and may further include an outer coupling body 60.

In this embodiment, the substrate support unit 10, the laser generation unit 20, the laser transfer unit 30, the light transmitter transfer unit 40, and the first light transmitter 51 are the same as the aforementioned embodiment, so overlapping descriptions are omitted, and the outer coupling body which differs from the aforementioned embodiments will be mainly described.

The outer coupling body 60 is formed to surround an outside of the first light transmitter 51. In this case, the outer coupling body 60 is formed to surround only an outside except for a top end and a bottom end of the first light transmitter 51, so that the laser does not pass through the outer coupling body 60 but passes through only the first light transmitter 51. In addition, the outer coupling body 60 is formed so a bottom part is immersed in the chemical 2. The outer coupling body 60 allows the laser passing through the first light transmitter 51 to be reflected by the outer coupling body 60. Therefore, the laser passing through the first light transmitter 51 is prevented from being lost by being refracted outside the outer surface of the first light transmitter 51 by the outer coupling body 60. In this case, a refractive index of the outer coupling body 60 is formed to have a lower refractive index than that of the first light transmitter 51, or an inner surface of the outer coupling body 60 is formed of a reflective layer with a high reflectivity, preventing a loss of energy of the laser by preventing the laser from being refracted outside the outer coupling body 60.

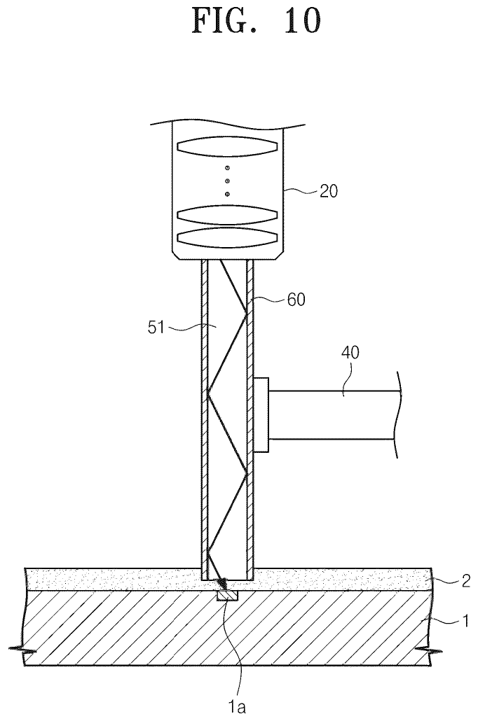

FIG. 11 is a block view of the substrate treating apparatus according to another embodiment of the inventive concept.

Referring further to FIG. 11, the substrate treating apparatus according to another embodiment of the inventive concept includes the substrate support unit 10, the laser generation unit 20, the laser transfer unit 30, the light transmitter transfer unit 40, and further includes a third light transmitter 53.

In this embodiment, the substrate support unit 10, the laser generation unit 20, the laser transfer unit 30, and the light transmitter transfer unit 40 are the same as the above embodiment, so overlapping descriptions are omitted, and the third light transmitter 53 which differs from the aforementioned embodiment will be mainly described.

The third light transmitter 53 is formed in a rod shape and is disposed on the laser irradiation path of the laser generation unit 20. In this case, the third light transmitter 53 is placed only at a partial region of a laser irradiation path of the laser generation unit 20, and in this case, the bottom portion of the third light transmitter 53 is placed to be immersed in the chemical 2. Since the third light transmitter 53 is not positioned on the irradiation path of the laser and is placed only at a partial region of the chemical 2, there is a benefit that a risk of breakage of the third light transmitter 53 is less than that of the first light transmitter 51.

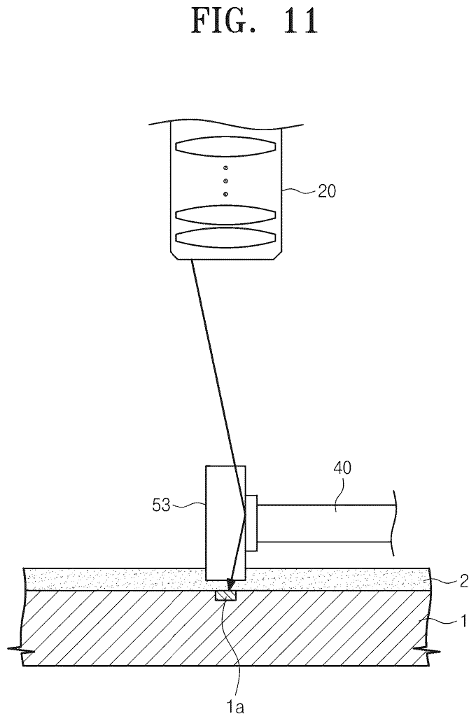

FIG. 12 is a block view of the substrate treating apparatus according to another embodiment of the inventive concept.

Referring further to FIG. 12, the substrate treating apparatus according to another embodiment of the inventive concept includes the substrate support unit 10, the laser generation unit 20, the laser transfer unit 30, the light transmitter transfer unit 40, and further includes a fourth light transmitter 54.

In this embodiment, the substrate support unit 10, the laser generation unit 20, the laser transfer unit 30, and the light transmitter transfer unit 40 are the same as the above embodiment, so overlapping descriptions are omitted, and the fourth light transmitter 54 which differs from the aforementioned embodiment will be mainly described.

The fourth light transmitter 54 is formed in a rod shape and is disposed on the laser irradiation path of the laser generation unit 20. In this case, the fourth light transmitter 54 is placed only at a partial region of the laser irradiation path of the laser generation unit 20, and a bottom portion of the fourth light transmitter 54 is placed to be immersed in the chemical 2. Since the fourth light transmitter 54 is not positioned on the irradiation path of the laser, but is placed only at a region of the chemical 2, there is a benefit that a risk of breakage of the fourth light transmitter 54 is less than that of the first light transmitter 51.

In addition, the fourth light transmitter 54 has an outer surface downwardly inclined so that a diameter of a cross-section narrows along a downward direction. Since the cross-section of the fourth light transmitter 54 narrows toward a bottom portion, a laser angle deviation near the bottom portion becomes less than an angle deviation of the first light transmitter 51. Therefore, since the fourth light transmitter 54 transmits the laser immersed in the chemical 2, an irradiation region of the laser does not deviate from the target region 1a even if the shaking angle of the chemical 2 is out of an allowable range due to a vibration or an airflow, and the laser angle deviation is smaller than that of the first light transmitter 51 so the substrate 1 can be more precisely etched than the first light transmitter 51.

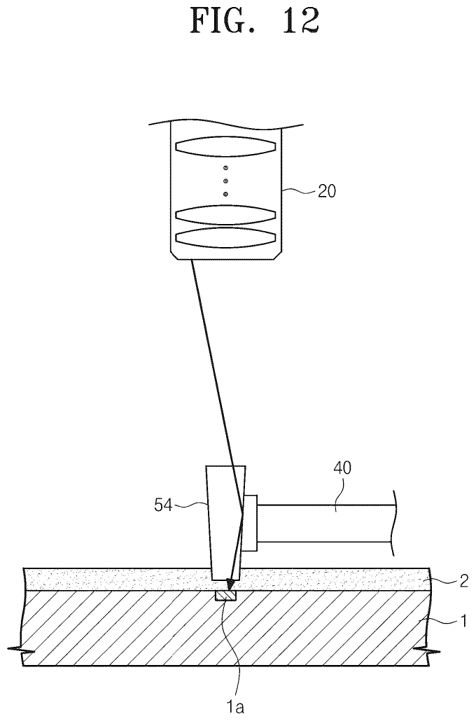

FIG. 13 is a block view of the substrate treating apparatus according to another embodiment of the inventive concept.

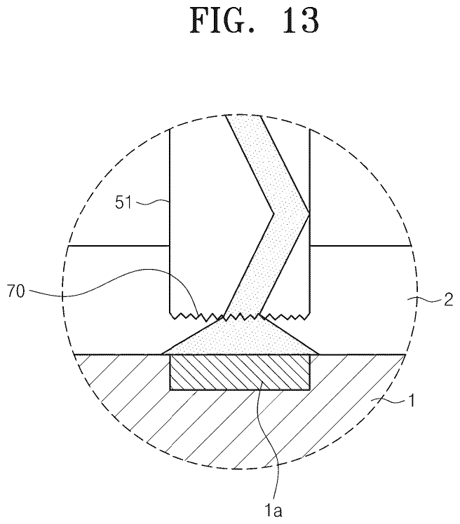

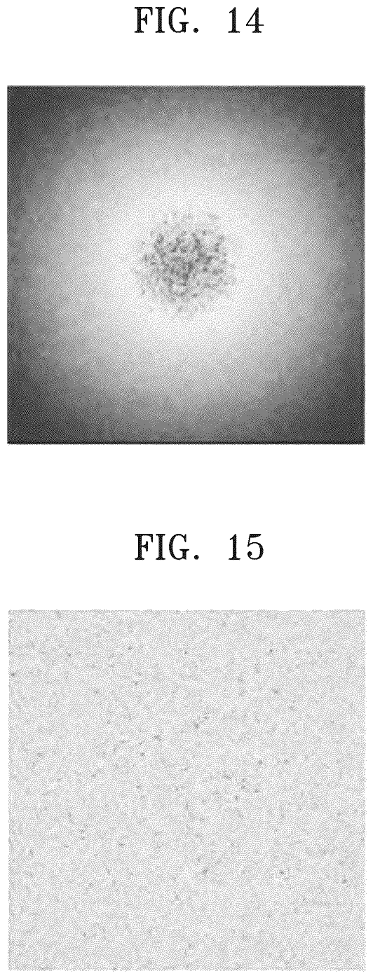

FIG. 14 is an image of the energy density distribution of the laser before a diffusion unit 70 shown in FIG. 13 is formed, and FIG. 15 is an image of an energy density of a laser which has passed through the diffusion unit 70 after the diffusion unit 70 shown in FIG. 13 is formed.

According to FIG. 13 to FIG. 15, the substrate treating apparatus according to another embodiment of the inventive concept includes the substrate support unit 10, the laser generation unit 20, the laser transfer unit 30, the light transmitter transfer unit 40, the first light transmitter 51, and further includes a diffusion unit 70.

In this embodiment, the substrate support unit 10, the laser generation unit 20, the laser transfer unit 30, the light transmitter transfer unit 40, and the first light transmitter 51 are the same as the aforementioned embodiment, so overlapping descriptions are omitted, and the diffusion unit 70 which differs from the aforementioned embodiment will be mainly described.

The diffusion unit 70 is formed under the first light transmitter 51. The diffusion unit 70 is formed by irregularly distributing a plurality of fine grooves or protrusions under the first light transmitter 51. In addition, the diffusion unit 70 may be configured in a form in which a plate with multiple fine grooves or protrusions is irregularly distributed is coupled to an end of the first light transmitter 51. As shown in FIG. 14, the diffusion unit 70 is a configuration to improve an issue of a density of the laser passing through the first light transmitter 51 being the largest near the center, so that a uniform etching is not performed throughout an entire irradiation region of the laser.

Regarding the diffusion unit 70, as described in FIG. 15, if the laser transmitted through the first light transmitter 51 is irradiated through the bottom portion of the first light transmitter 51, the energy density of the laser is concentrated in a partial region and is not irradiated, and a light transmitted by an irregular distribution of fine grooves or protrusions is diffused. Therefore, the laser passing through the first light transmitter 51 is uniformly distributed throughout the entire irradiation region without concentrating the energy density in a specific region, so that a uniform etching can be performed in the region at which the laser is irradiated.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a substrate support unit configured to support a substrate having a chemical coated thereon;
a laser generation unit configured to irradiate a laser to the substrate; and
a light-transmitter positioned along a path at which the laser is irradiated.

2. The substrate treating apparatus of claim 1, further comprising a light-transmitter transfer unit coupled to the light-transmitter and configured to transfer the light-transmitter.

3. The substrate treating apparatus of claim 1, wherein a cross section of the light-transmitter is shaped as any one among a circle, an oval, a square, or a polygon.

4. The substrate treating apparatus of claim 1, wherein the light-transmitter is positioned so a bottom portion thereof is immersed in the chemical.

5. The substrate treating apparatus of claim 4, wherein the bottom portion of the light-transmitter is positioned apart from the substrate.

6. The substrate treating apparatus of claim 1, wherein the light-transmitter is formed having an outer surface inclined toward a bottom direction so a diameter of a cross section becomes smaller toward a bottom.

7. The substrate treating apparatus of claim 1 further comprising an outer coupling body formed to surround an outer side of the light-transmitter.

8. The substrate treating apparatus of claim 7, wherein the outer coupling body is formed at a region aside from a top and a bottom of the light-transmitter, and
the outer coupling body is formed having a lower refractive index than a refractive index of the light-transmitter or having a reflective surface with a high reflectivity on an inner side surface.

9. The substrate treating apparatus of claim 1, wherein the light-transmitter is positioned only at a partial region among a laser irradiation path.

10. The substrate treating apparatus of claim 1, further comprising a diffusion unit configured to diffuse a laser which has passed through the light-transmitter, and which is composed at a bottom of the light-transmitter.

11. A substrate treating apparatus of claim 10, wherein the diffusion unit has a plurality of grooves or a plurality of protrusions which are irregularly distributed.

12. A substrate treating method comprising:
seating a substate on a substrate support unit;
positioning a laser generation unit at a top space of the substrate by transferring with a laser transfer unit;
positioning a light-transmitter along a laser path of which a laser is irradiated from the laser generation unit with a light-transmitter transfer unit;
irradiating the laser from the laser generation unit to the light-transmitter and transmitting the laser to a target region of the substrate by the light-transmitter; and
etching the substrate by a laser which has reached the target region.

13. The substrate treating method of claim 12, wherein a bottom portion of the light-transmitter is positioned to be immersed in a chemical at the positioning the light-transmitter.

14. The substrate treating method of claim 13, wherein a bottom portion of the light-transmitter is positioned apart from the substrate.

15. The substrate treating method of claim 13, wherein the light-transmitter is formed having an outer surface inclined toward a bottom direction so a diameter of a cross section becomes smaller toward a bottom.

16. The substrate treating method of claim 13, further comprising an outer coupling body formed to surround an outer side of the light-transmitter.

17. The substrate treating method of claim 16, wherein the outer coupling body is formed at a region aside from a top and a bottom of the light-transmitter, and
the outer coupling body is formed having a lower refractive index than a refractive index of the light-transmitter or having a reflective surface with a high reflectivity on an inner side surface.

18. The substrate treating method of claim 13, wherein the light-transmitter is positioned only at a partial region among a laser irradiation path.

19. The substrate treating method of claim 13, further comprising a diffusion unit at a bottom of the light-transmitter configured to diffuse a laser which has passed through the light-transmitter.

20. A substrate treating apparatus comprising:
a substrate support unit configured to support a substrate having a chemical coated thereon;
a laser generation unit configured to irradiate a laser to the substrate;
a light-transmitter positioned along a path at which the laser is irradiated;
a light-transmitter transfer unit coupled to the light-transmitter and configured to transfer the light-transmitter;
an outer coupling body formed to surround an outer side of the light-transmitter; and
a diffusion unit configured to diffuse a laser which has passed through the light-transmitter, and which is composed at a bottom of the light-transmitter, and
wherein a cross section of the light-transmitter is shaped as any one among a circle, an oval, a square, or a polygon,
the light-transmitter is positioned to a bottom portion thereof is immersed in the chemical,
the bottom portion of the light-transmitter is positioned apart from the substrate,
the light-transmitter is formed having an outer surface inclined toward a bottom direction so a diameter of a cross section becomes smaller toward a bottom,
the outer coupling body is formed at a region aside from a top and a bottom of the light-transmitter,
the outer coupling body is formed having a lower refractive index than a refractive index of the light-transmitter or having a reflective surface with a high reflectivity on an inner side surface,
the light-transmitter is positioned only at a partial region among a laser irradiation path, and
the diffusion unit has a plurality of grooves or a plurality of protrusions which are irregularly distributed.
